(19) United States
(12) Patent Application Publication
(10) Pub. No.: US 2019/0203113 A1
(43) Pub. Date: Jul. 4, 2019

(54) PEROVSKITE QUANTUM DOT, METHOD OF PREPARING THE SAME AND QUANTUM DOT FILM INCLUDING THE SAME

(71) Applicant: NATIONAL TSING HUA UNIVERSITY, HSINCHU (TW)

(72) Inventors: HAO-WU LIN, HSINCHU (TW); SHU-WEN DAI, HSINCHU (TW); BO-WEI HSU, HSINCHU (TW)

(21) Appl. No.: 15/984,184

(22) Filed: May 18, 2018

(30) Foreign Application Priority Data
Jan. 4, 2018 (TW) 107100319

(51) Int. Cl. C09K 11/06; C07F 7/24; H01L 51/00

(52) U.S. Cl. CPC C09K 11/06; H01L 51/502; H01L 51/0077; C07F 7/24

(57) ABSTRACT

A method of preparing perovskite quantum dots is provided. The method includes: adding an organic ligand into a first precursor solution prepared by a first halide and a second halide to form a second precursor solution, or adding the organic ligand into a first poor solvent to form a second poor solvent; spraying the first precursor solution into the second poor solvent or spraying the second precursor solution into the first poor solvent by a spraying method to obtain a mixed solution including first perovskite quantum dots and second quantum dots; centrifuging the mixed solution to obtain supernatant and precipitate; and obtaining the first perovskite quantum dots and the second perovskite quantum dots from the supernatant and the precipitate, respectively. The first perovskite quantum dots are different from the second perovskite quantum dots.

### CROSS-REFERENCE TO RELATED APPLICATION

This application claims priority from Taiwan Patent Application No. 107100319, filed on Jan. 4, 2018 at Taiwan Intellectual Property Office, the contents of which are hereby incorporated by reference in their entirety for all purposes.

### BACKGROUND OF THE INVENTION

### 1. Field of the Invention

The present invention is related to perovskite quantum dots, in particular, is related to perovskite quantum dots, a method of preparing the same and a quantum dot film comprising the same.

### 2. Description of the Related Art

Quantum dots are a nano-material having a length below 100 nm in all of three dimensions, having a tiny dot-like appearance and are composed of very few atoms. The movement of electrons within the quantum dot in various directions is limited to the volume of the quantum dot, thereby amplifying the influence caused by “Quantum Confinement Effect”. Due to the discontinuities of energy level caused by the quantum confinement effect, the density of states (DOS) within the quantum dot is variable depending on the size of the dot thereof, so that the optical, electrical and magnetic properties are variable depending on the size of the quantum dot as a result. Recently, quantum dot technology is popular because of its narrow full width with half maximum (FWHM) in emission spectrum, high quantum yield and the optical property of being able to adjust the emission wavelength by modifying the composition and size.

So far, research on quantum dots has mainly been focused on perovskite quantum dots, II-VI group semiconductor quantum dots and III-V group semiconductor quantum dots. An exemplary example of the II-VI group semiconductor quantum dots is CdSe quantum dots. Because of better crystallization properties, fewer defects, and great photoelectric properties of CdSe quantum dots, they have become the most widely studied and applied quantum dots so far. However, CdSe quantum dots are still considered as having problems with containing the heavy metal element cadmium (Cd), as well as complex manufacturing processes and high cost.

An exemplary example of the III-V group semiconductor quantum dots is InP quantum dots. The InP quantum dots do not contain the heavy metal element cadmium (Cd). However, they have relatively poor crystallization properties, low quantum yield, poor chemical stability, and have the problems of complex manufacturing process and high cost.

The perovskite quantum dots are mainly classified into full inorganic perovskite quantum dots and perovskite quantum dots depending on the composition of the perovskite quantum dot. The presented full inorganic perovskite quantum dot has excellent emission properties, narrow full width with half maximum (FWHM) in emission spectrum, and high stability. However, the synthesis process is relatively complex and the cost is higher. The perovskite quantum dots have advantages of adjustable color, well defined monochromaticity and simple synthesis process. The perovskite quantum dots are considered as able to provide very high quantum yield. Nevertheless, they are still unstable.

### SUMMARY OF THE INVENTION

With respect to the presented problems of recent techniques, the present invention provides perovskite quantum dots with improved crystalline properties, quantum yield and stability, the manufacturing method of the same and the quantum dot film of the same.

An aspect of the present invention provides a method of preparing perovskite quantum dots, comprising: adding an organic ligand into a first precursor solution prepared by a first halide and a second halide to form a second precursor solution, or adding the organic ligand into a first poor solvent to form a second poor solvent; spraying the first precursor solution into the second poor solvent or spraying the second precursor solution into the first poor solvent by a spraying method to obtain a mixed solution comprising first perovskite quantum dots and second perovskite quantum dots; centrifuging the mixed solution to obtain a supernatant and a precipitate; and obtaining the first perovskite quantum dots and the second perovskite quantum dots from the supernatant and the precipitate, respectively, wherein, the first perovskite quantum dots are different from the second perovskite quantum dots.

Preferably, the first halide is an inorganic metal halide of which the metal is selected from the elemental group consisting of: Ge, Sn, Pb, Sb, Bi, Cu, Mn, Ca, In, Tl, Pd, Pt and combinations thereof.

Preferably, the first halide is a lead halide.

Preferably, the second halide is an organic ammonium salt or an inorganic halide.

Preferably, the inorganic halide is a cesium halide.

Preferably, the organic ammonium salt may be represented by Formula 1 as follows:

N(R₁)₄Q (Formula 1)

Wherein, R₁ is H, a substituted or unsubstituted C₁₋₂₀ alkyl group, a substituted or unsubstituted C₁₋₂₀ cycloalkyl group, a substituted or unsubstituted C₆₋₂₀ aromatic group or —N(R₂)₃; wherein R₂ is H, a C₁₋₂₀ alkyl group, C₁₋₂₀ a cycloalkyl group or C₆₋₂₀ aromatic group; R₁ may each be the same or not the same, and R₂ may each be the same or not the same; and Q is I, Cl or Br. The substituted C₁₋₂₀ alkyl group, the substituted C₁₋₂₀ cycloalkyl group or the substituted C₆₋₂₀ aromatic group may be the C₁₋₂₀ alkyl group, the C₁₋₂₀ cycloalkyl group or the C₆₋₂₀ aromatic group of which at least one of the hydrogen atoms are substituted by a C₁₋₂₀ alkyl group, a C₁₋₂₀ cycloalkyl group, a C₆₋₂₀ aromatic group or —N(R₃)₃; wherein R₃ is H, a C₁₋₂₀ alkyl group, a C₁₋₂₀ cycloalkyl group or a C₆₋₂₀ aromatic group, When at least two of R₁ are substituted or unsubstituted C₁₋₂₀ alkyl groups or —N(R₂)₃, the at least two of R₁ are optionally bonded to form a heterocyclic ring with N.

Preferably, the organic ligand comprises a carbon chain having at least 5 carbon atoms.

Preferably, the organic ligand comprises a compound represented by Formula 2 as follows:

CₙH₂ₙ₊₁NH₂ (Formula 2)

wherein, n is an integral selected from 1 to 30.

Preferably, the organic ligand comprises a compound represented by Formula 3 as follows:

CₙH₂ₙ₋₁COOH (Formula 3)

wherein, n is an integral selected from 1 to 30.

Preferably, the droplets of the first precursor solution or the second precursor solution sprayed by the spraying method have a diameter of 10⁻¹˜10⁻² mm.

Preferably, the first perovskite quantum dot has a sphere shape, and the second perovskite quantum dot has a cubic or rectangular shape.

Preferably, the structures of the first perovskite quantum dots and the second perovskite quantum dots comprise: an inner core including the compound represented by (N(R₁)₄)XYₐZ₃₋ₐ and a plurality of organic ligands formed on the surface of the inner core. Wherein, the definition of R₁ is the same as R₁ described in Formula 1; Y and Z each individually is I, Cl or Br; X is selected from an elemental group consisting of Ge, Sn, Pb, Sb, Bi, Cu, Ca, In, Tl, Pd, Pt, Mn and combinations thereof; and a is an integral selected from 1 to 3.

Another aspect of the present invention provides perovskite quantum dots, which are the first perovskite quantum dots and the second peroskite quantum dots prepared by the aforementioned method.

Yet another aspect of the present invention provides a quantum dot film comprising the aforementioned perovskite quantum dot.

### BRIEF DESCRIPTION OF THE DRAWINGS

FIG. 1 illustrates a flow chart showing the method of preparing the perovskite quantum dots of the embodiments of the present invention.

FIG. 2 illustrates standardized fluorescent spectrums of the perovskite quantum dots of an example of the present invention and a comparative example.

FIG. 3 illustrates a standardized fluorescent spectrum of the perovskite quantum dots of another example of the present invention.

FIG. 4 illustrates standardized fluorescent spectrums of the perovskite quantum dots of another example and the quantum dot film formed by the same.

FIG. 5 illustrates TEM results of the perovskite quantum dots of a comparative example as part (a) and an example of the present invention as part (b).

FIG. 6 includes a part (a) illustrating the TEM results of the perovskite quantum dots of another example of the present invention; and a part (b) illustrating the high resolution TEM (HR-TEM) results and the Fast Fourier Transform (FFT) results of the perovskite quantum dots represented in the part (a).

FIG. 7 includes a part (a) illustrating the two-dimensional grazing incidence wide angle x-ray scattering (GIWAXS) results of the quantum dot film comprising the perovskite quantum dots of the comparative example; a part (b) illustrating the two-dimensional GIWAXS results of the quantum dot film comprising the perovskite quantum dots of an example of the present invention; a part (c) illustrating the two-dimensional GIWAXS results of the quantum dot film comprising the perovskite quantum dots of another example of the present invention; a part (d) illustrating the ring-averaged GIWAXS profile corresponding to the part (c) of FIG. 7; a part (e) illustrating the grazing incidence small angle x-ray scattering GISAXS result of quantum dot films I, II and V; and a part (f) illustrating a schematic diagram of the quantum dot film II formed on a substrate.

FIG. 8 illustrates a diagram obtained by an integrating sphere measuring system, which represents the change of quantum yield over time of a quantum dot solution comprising the perovskite quantum dots of an example and a comparative example of the present invention.

FIG. 9 illustrates a diagram obtained by an integrating sphere measuring system, which represents the change of quantum yield over time of a quantum dot solution comprising the quantum dot film of the perovskite quantum dots of another example of the present invention.

FIG. 10 includes a part (a) illustrating a schematic diagram of utilizing the quantum dot film of an example of the present invention as a light conversion layer applied in a light-emitting display device; a part (b) illustrating the photographs of the part (a); a part (c) illustrating a diagram of the IVL properties of the light-emitting display device shown in the part (a), wherein the asterisks represents the brightness measured by a spectroradiometer; a part (d) illustrating a diagram of the EQE and the efficiency of the light-emitting display device shown in the part (a); and a part (e) illustrating a emission spectrum of the light-emitting display device (ccQD-LED) shown in the part (a) and a emission spectrum of the light-emitting display device without comprising the quantum dot film of the present invention.

FIG. 11 includes a part (a) illustrating a schematic diagram of utilizing the quantum dot film of an example of the present invention as a light-emitting layer applied in a light-emitting display device; a part (b) illustrating a diagram of the J-V-L property of the light-emitting display device shown in the part (a); a part (c) illustrating a diagram of the EQE and the efficiency of the light-emitting display device shown in the part (a); and a part (d) illustrating a emission spectrum of the light-emitting display device shown in the part (a).

### DESCRIPTION OF THE PREFERRED EMBODIMENTS

For ease of understanding the features, content, advantages and benefits provided by the present invention, the invention will be described in details by embodiments taken in conjunction of drawings hereinafter. The described embodiments are merely exemplary disclosure for ease of explaining the invention, but are not intended to limit the scope of the invention.

The “C₁₋₂₀ alkyl group” or “unsubstituted C₁₋₂₀ alkyl group” used herein represents the linear or branched alkyl groups having 1 to 20 carbon atoms, of which all of the hydrogen atoms are unsubstituted by substitution groups. The examples of the C₁₋₂₀ alkyl group include but are not limited to a methyl group, an ethyl group, a propyl group, an isobutyl group, a sec-butyl group, a pentyl group, an isopentyl group and a hexyl group. Equally, the “C₁₋₅ alkyl group” used herein represents the linear or branched alkyl groups having 1 to 5 carbon atoms, of which all of the hydrogen atoms are unsubstituted by substitution groups. The examples of the C₁₋₅ alkyl group include but are not limited to a methyl group, an ethyl group and a propyl group.

The “C₁₋₂₀ cycloalkyl group” or “unsubstituted C₁₋₂₀ cycloalkyl group” used herein represents the cycloalkyl groups having 1 to 20 carbon atoms, of which all of the hydrogen atoms are unsubstituted by substitution groups. The examples of the C₁₋₂₀ cycloalkyl group include but are not limited to a cyclobutyl group, a cyclopentyl group and a cyclohexyl group.

The “C₆₋₂₀ aromatic group” or “unsubstituted C₆₋₂₀ aromatic group” used herein represents the aromatic groups having 6 to 20 carbon atoms, of which all of the hydrogen atoms are unsubstituted by substitution groups. The examples of the C₆₋₂₀ aromatic group include by are not limited to a phenyl group, a naphthyl group and an anthryl group.

The “substituted C₁₋₂₀ alkyl group”, “substituted C₁₋₂₀ cycloalkyl group”, substituted C₆₋₂₀ aromatic group” and “substituted ammonium salt” used herein represents a C₁₋₂₀ alkyl group, a C₁₋₂₀ cycloalkyl group, a C₆₋₂₀ aromatic group or a ammonium salt of which at least one of the hydrogen atoms are substituted by a C₁₋₂₀ alkyl group, a C₁₋₂₀ cycloalkyl group, a C₆₋₂₀ aromatic group or a ammonium salt.

The “quantum yield” used herein represents the ratio of emitted photon numbers after light adsorption and the absorbed photon numbers of a quantum dot.

The “quantum dot” used herein represents the quantum dots having an inner core and organic ligands formed on the surface of the inner core. The “perovskite quantum dot” used herein represents the quantum dots having an inner core which has the same crystalline structure as calcium titanate (CaTiO₃), of which the Formula of the inner core has an organic or inorganic anion, metal ion and halogen ion.

The “organic ligands” used herein represents the atoms, molecules and/or ions which is able to generate a bonding with the inner core of the quantum dot, to be formed on the surface of the inner core for covering the surface, and thereby to form perovskite quantum dots with perfect crystalline.

The “precursor solution” used herein represents a highly polar solvent for forming the inner core of the perovskite quantum dot, which contains a first halide and a second halide dispersed therein. The “poor solvent” used herein represents a lowly polar solvent having a polarity index lower than the precursor solution, which generates the perovskite quantum dot when mixing with the precursor solution.

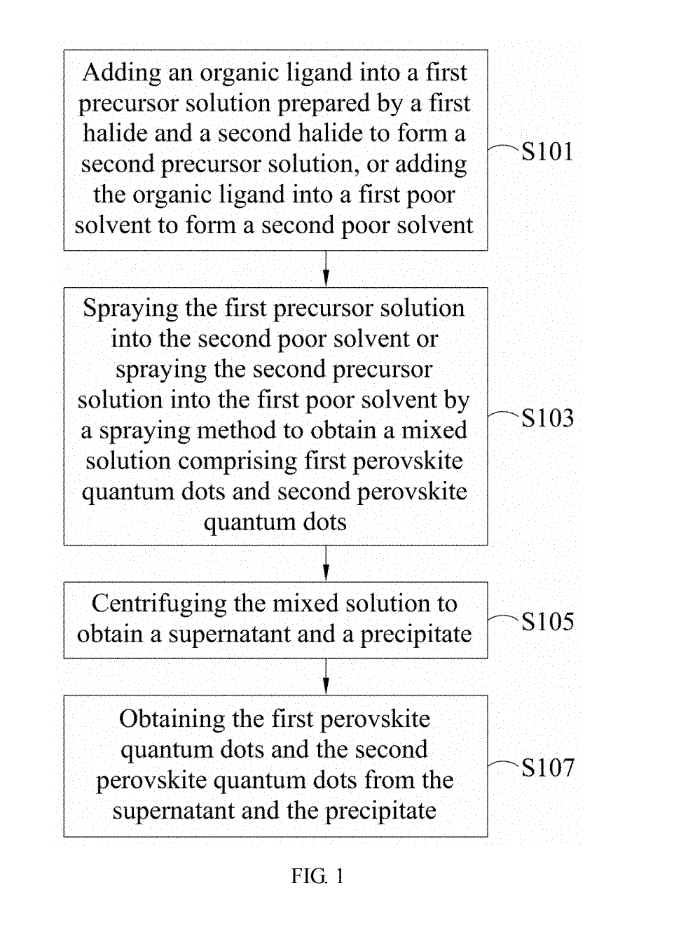

FIG. 1 represents a schematic diagram illustrating the method of preparing the perovskite quantum dots of the embodiments of the present invention. As shown in FIG. 1, the method of preparing perovskite quantum dots provided by the embodiment of the present invention comprises: a step S101 of adding an organic ligand into a first precursor solution prepared by a first halide and a second halide to form a second precursor solution, or adding the organic ligand into a first poor solvent to form a second poor solvent; a step S103 of spraying the first precursor solution into the second poor solvent or spraying the second precursor solution into the first poor solvent by a spraying method to obtain a mixed solution comprising first perovskite quantum dots and second perovskite quantum dots; a step S105 of centrifuging the mixed solution to obtain a supernatant and a precipitate; and a step S107 of obtaining the first perovskite quantum dots and the second perovskite quantum dots from the supernatant and the precipitate, respectively.

In step S101, an organic ligand is added into a first precursor solution prepared by a first halide and a second halide to form a second precursor solution, or the organic ligand is added into a first poor solvent to form a second poor solvent. The “first precursor solution” represents a highly polar solvent, having a polarity index>5.0 and containing a first halide and a second halide dispersed therein in a free state, for forming the perovskite quantum dots, wherein the solution does not contain the organic ligands. The “second precursor solution” represents a highly polar solvent, having a polarity index>5.0 and containing a first halide and a second halide dispersed therein in a free state, for forming the perovskite quantum dots, wherein the solution further contains the organic ligands. The examples of the highly polar solvent having a polarity index>5.0 may include but not limited to N,N-dimethylformamide (DMF), acetone, dimethyl sulfoxide (DMSO), acetonitrile, γ-butyrolactone (GBL), N-methyl-2-pyrrolidone (NMP) or a combination thereof.

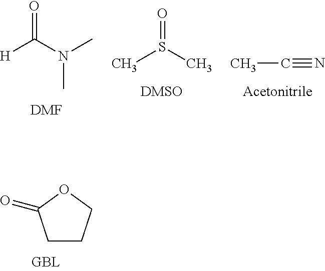

The “first poor solvent” represents a lowly polar solvent without containing the organic ligands and having a polarity index<2.5; whereas the “second poor solvent” represents a lowly polar solvent containing the organic ligands and having a polarity index<2.5. The lowly polar solvent without containing the organic ligands and having a polarity index<2.5 may include but not limited to toluene, o-xylene, chloroform, hexane, cyclohexane, ethyl acetate, diethyl ether or a combination thereof.

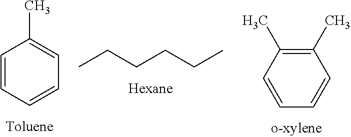

In an embodiment, the first halide may be an iodide, bromide, chloride or a combination thereof of an organic metal selected from a group consisting of Ge, Sn, Pb, Sb, Bi, Cu, Mn, Ca, In, Tl, Pd and Pt. In a preferable embodiment, the first halide may be a lead halide, preferably PbBr₂, PbCl₂, PbI₂ or a combination thereof. In an embodiment, the second halide may be an organic ammonium salt or an inorganic halide. When the second halide is an inorganic halide, it may be a cesium halide. When the second halide is an organic ammonium salt, it may be an organic ammonium salt represented by the Formula 1 shown below:

N(R₁)₄Q (Formula 1)

In Formula 1, R₁ is H, a substituted or unsubstituted C₁₋₂₀ alkyl group, a substituted or unsubstituted C₁₋₂₀ cycloalkyl group, a substituted or unsubstituted C₆₋₂₀ aromatic group or —N(R₂)₃, and R₁ may each be the same or not the same; R₂ is H, a C₁₋₂₀ alkyl group, a C₁₋₂₀ cycloalkyl group or a C₆₋₂₀ aromatic group, and R₂ may each be the same or not the same. For example, the three R₁ of (R₁)₄ may be H and another may be a methyl group. The substituted C₁₋₂₀ alkyl group, the substituted C₁₋₂₀ cycloalkyl group or the substituted C₆₋₂₀ aromatic group may be the C₁₋₂₀ alkyl group, the C₁₋₂₀ cycloalkyl group or the C₆₋₂₀ aromatic group of which at least one of the hydrogen atoms are substituted by a C₁₋₂₀ alkyl group, a C₁₋₂₀ cycloalkyl group, a C₆₋₂₀ aromatic group or —N(R₃)₃, wherein R₃ is H, a C₁₋₂₀ alkyl group, a C₁₋₂₀ cycloalkyl group or a C₆₋₂₀ aromatic group, and R₃ may each be the same or not the same. When at least two of R₁ are substituted or unsubstituted C₁₋₂₀ alkyl groups or —N(R₂)₃, the at least two of R₁ are optionally bonded to form a heterocyclic ring with N. For example, the at least two of R₁ may be bonded with each other to form a heterocyclic ring such as pyrrolidine with N. For example, (R₁)₄N may be but not limited to:

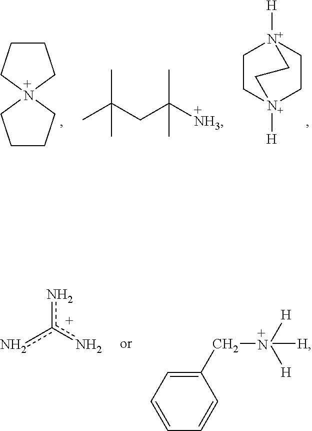

wherein Q is I, Cl or Br. In a preferable embodiment, the second halide may be CH₃NH₃Br, CH₃NH₃I, CH₃NH₃Cl, CsCl, CsBr or CsI.

In an embodiment, the organic ligand may include a carbon chain having at least 5 carbon atoms. In a preferable embodiment, the organic ligand including a carbon chain having at least 5 carbon atoms may include but not limited to oleic acid, n-octylamine, oleylamine or a combination thereof.

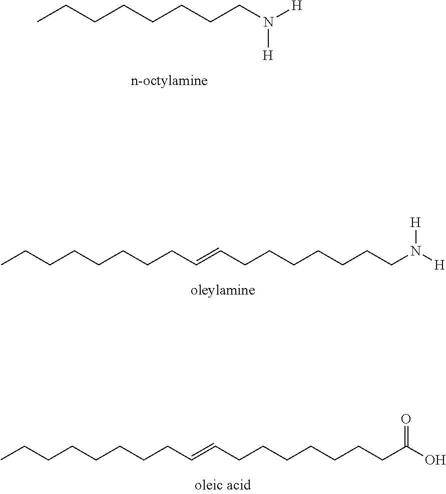

In an embodiment, the organic ligand may include the organic amines represented by Formula 2 and/or the organic acids represented by Formula 3 shown as below:

CₙH₂ₙ₊₁NH₂ (Formula 2)

CₙH₂ₙ₋₁COOH (Formula 3)

In Formulas 2 and 3, n is an integer selected from 1 to 30, and the n of Formulas 2 and 3 may be the same or not the same as each other. In an embodiment, the n of Formula 2 may be an integer selected from 5 to 20, and the n of Formula 3 may be an integer selected from 2 to 20.

In step S103, by utilizing an apparatus such as an automatic sprayer which is able to spray a solution in a nebulized form, the nebulized first precursor solution is sprayed into the second poor solvent or the nebulized second precursor solution is sprayed into the first poor solvent by a spraying method to mix the organic ligands, the first precursor solution and the first poor solvent, and to form a mixed solution including the first perovskite quantum dots which may have a sphere shape and the second perovskite quantum dots which may have a cubic or rectangular shape.

The apparatus and the condition for spraying the first precursor solution and the second precursor solution in a nebulized form are not particularly limited and is acceptable as long as the apparatus and the condition is able to spray droplets having a diameter of 10⁻¹˜10⁻² mm. In the present step, because of the low solubility of the poor solvent against the first halide and the second halide including in the precursor solution, a mixed solution including the first perovskite quantum dots and the second perovskite quantum dots will be formed.

The first perovskite quantum dots and the second perovskite quantum dots may have an inner core having the structure represented by (N(R₁)₄)XYₐZ₃₋ₐ, wherein R₁ is the same as R₁ of Formula 1. Y and Z each individually is I, Cl or Br; X is selected form a group consisting of Ge, Sn, Pb, Sb, Bi, Cu, Ca, In, Tl, Pd, Pt, Mn and a combination thereof; and a is an integral selected from 1 to 3. In an embodiment, the formed perovskite quantum dots may have an inner core having a structure represented by (CH₃NH₃)PbBr₂Cl, (CH₃NH₃)PbBrI₂, or (CH₃NH₃)PbBr₃.

Subsequently, in step S105, the mixed solution of step S103 is centrifuged to obtain a supernatant and a precipitate. Finally, in step S107, the first perovskite quantum dots and the second perovskite quantum dots are obtained from the supernatant and precipitate of step S105, respectively.

In step S107, the first perovskite quantum dots may be obtained from the separated supernatant of step S105; and the second pervoskite quantum dots may be obtained from the separated precipitate of step S105. In particular, the separated precipitate of step S105 may be re-dispersed in a lowly polar solvent having a polarity index<2.5 and further be re-centrifuged again, thereby the second perovskite quantum dots are obtained from the supernatant of the re-centrifuged product.

Herein, the advantages of the method of preparing the perovskite quantum dots and the prepare perovskite quantum dots provided by the embodiments of the present invention will be particularly explained based on the examples and the comparative examples provided below.

### EXAMPLE 1

0.08 mmol of CH₃NH₃Br and 0.08 mmol of PbBr₂ are dispersed in 10 mL of DMF in a 20 mL beaker. Then, the solution is mixed uniformly to obtain a first precursor solution I.

2 mL of oleic acid and 0.06 mL of n-octylamine are added into the first precursor solution I to obtain a second precursor solution I including organic ligands.

Next, nitrogen was used at room temperature, with an automatic sprayer (a SV-6 spray valve with 2.0 mm nozzle diameter, Musashi Engineering, Inc.) at a cylinder gas pressure of 10 KPa and a mixed gas pressure of 10 KPa, by which the second precursor solution I is sprayed into 50 mL of toluene until chartreuse color colloidal solution is generated.

The chartreuse color colloidal solution is transferred into a centrifuge tube and is centrifuged at 6000 rpm for 10 minutes. Then, a quantum dot solution containing the perovskite quantum dots I are obtained (CH₃NH₃PbBr₃) by taking out the supernatant by a dropper. The precipitate is then taken out and re-dispersed in hexane, thereby transferred into a centrifuge tube and centrifuged at 6000 rpm for 20 minutes. Subsequently, supernatant is taken out to obtain a quantum dot solution II containing the perovskite quantum dots II (CH₃NH₃PbBr₃).

### EXAMPLE 2

Except for substituting PbBr₂ by a mixture of 0.0556 g of PbCl₂ and 0.2202 g of PbBr₂, a mixed solution containing the perovskite quantum dots is prepared by the same means of example 1, and the mixed solution is then transferred into a centrifuge tube and is centrifuged at 6000 rpm for 10 minutes. The precipitate is then taken out and re-dispersed in hexane, thereby transferred into a centrifuge tube and centrifuged at 6000 rpm for 20 minutes. Subsequently, supernatant is taken out to obtain a quantum dot solution III containing the perovskite quantum dots III (CH₃NH₃PbBr_{2.5}Cl_{0.5}).

### EXAMPLE 3

Except for substituting PbBr₂ by a mixture of 0.1112 g of PbCl₂ and 0.1468 g of PbBr₂, a mixed solution containing the perovskite quantum dots is prepared by the same means of example 1, and the mixed solution is then transferred into a centrifuge tube and is centrifuged at 6000 rpm for 10 minutes. The precipitate is then taken out and re-dispersed in hexane, thereby transferred into a centrifuge tube and centrifuged at 6000 rpm for 20 minutes. Subsequently, supernatant is taken out to obtain a quantum dot solution IV containing the perovskite quantum dots IV (CH₃NH₃PbBr₂Cl).

### COMPARATIVE EXAMPLE

A mixed solution containing the perovskite quantum dots is prepared by titrating the second precursor solution I of example 1 into 50 mL of toluene in a beaker until a precipitate is obviously generated.

Then, the mixed solution is transferred to a centrifuge tube and is centrifuged at 6000 rpm for 10 minutes. Subsequently, the supernatant is taken out by a dropper to obtain a quantum dot solution V containing the perovskite quantum dots V (CH₃NH₃PbBr₃).

Then, examples 1 to 3 and the comparative example are compared as follows.

Light-Emitting Color Purity

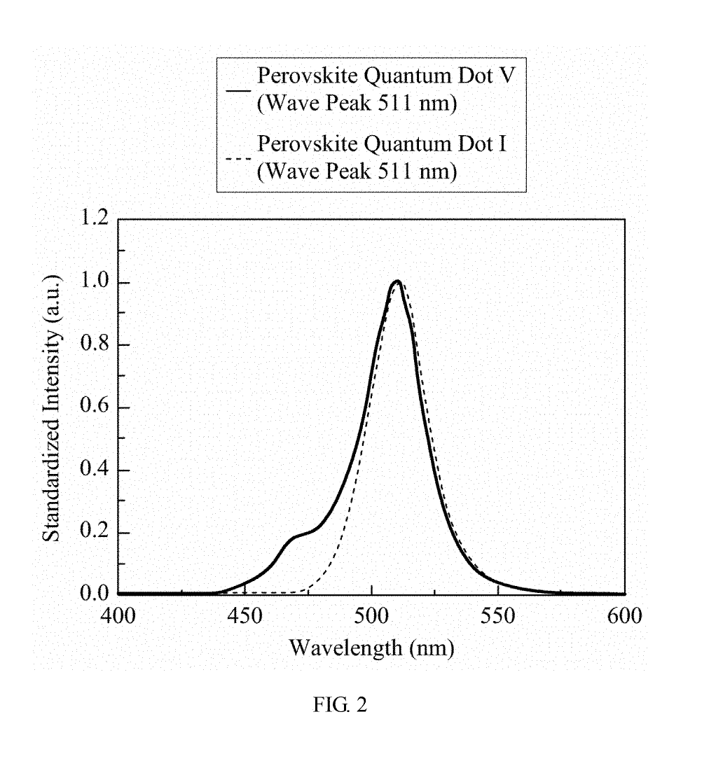

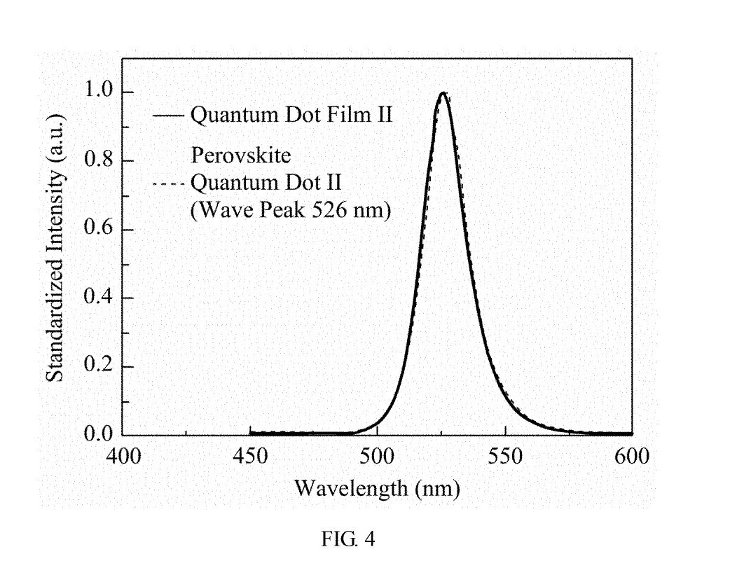

FIG. 2 represents the standardized fluorescent spectrum of the perovskite quantum dots I of the example of the present invention and the perovskite quantum dots V of the comparative example. FIG. 4 represents the standardized fluorescent spectrum of the perovskite quantum dots II of another example of the present invention and the quantum dot film II formed by the same, wherein the perovskite quantum dots II is represented by the dashed line and the quantum dot film formed by the same is represented by the solid line.

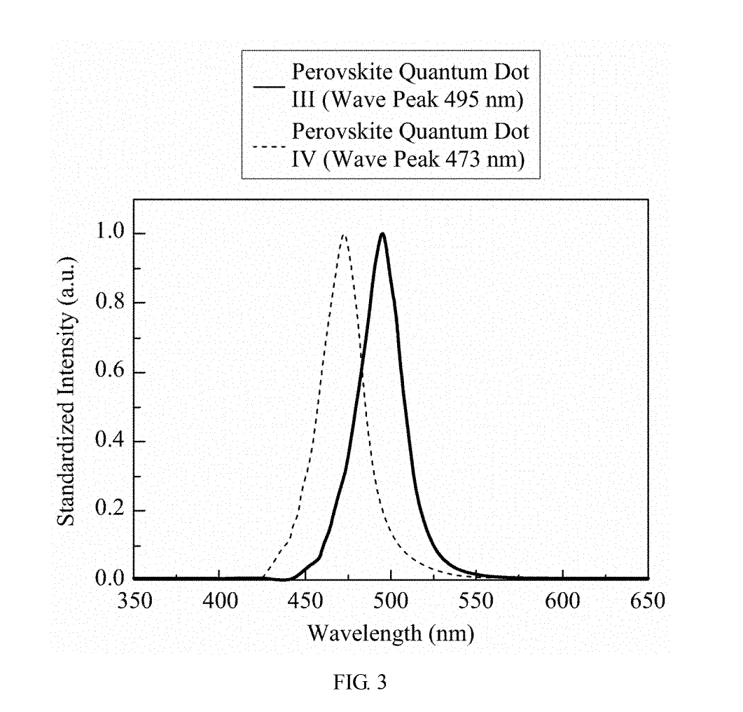

According to FIGS. 2 to 4, the perovskite quantum dots I, II and V may emit green light, and the perovskite quantum dots III and IV may emit blue light. Further, according to FIGS. 2 to 4, the perovskite quantum dots V of the comparative example has a relatively small peak at ˜470 nm, and the perovskite quantum dots I, II and perovskite quantum dots III, IV all have a half-width narrower than the perovskite quantum dots V. Hence, the perovskite quantum dots I to IV of the examples of the present invention may be proved as being able to emit a light more pure than that emitted by the perovskite quantum dots V of the comparative example. On the other hand, according to the measurement, the quantum yield of the perovskite quantum dots I is approaching 100%; the perovskite quantum dots II is approaching 100%; the perovskite quantum dots III is approaching 86%; the perovskite quantum dots IV is approaching 52%; and the perovskite quantum dots V is approaching 80%.

The crystalline properties of the perovskite quantum dots and the quantum dot film including the same.

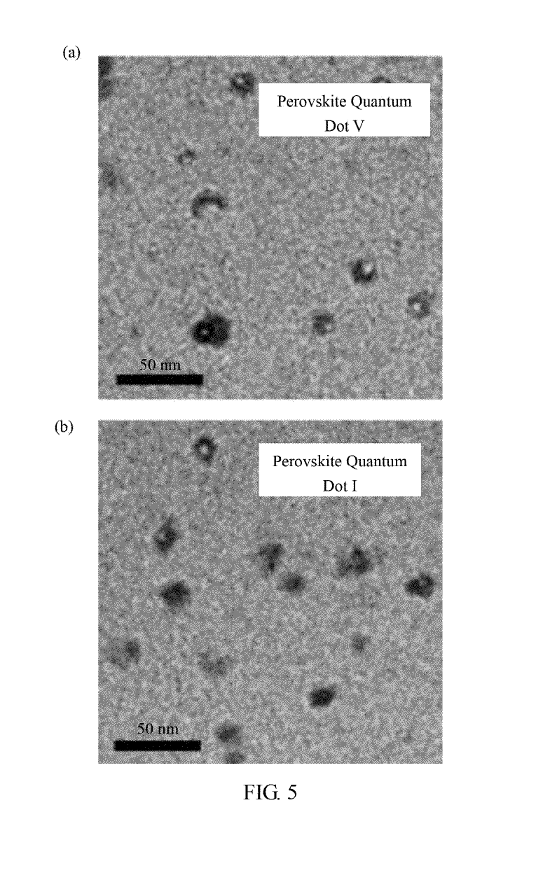

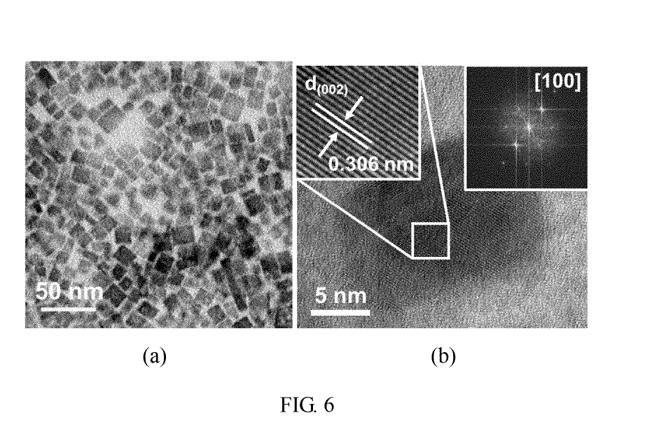

The crystalline properties of the perovskite quantum dots obtained from the supernatant and precipitate of the examples of the present invention and the comparative example and the quantum dot film formed by the same are described in detail as referring to the perovskite quantum dots I, II and V. FIG. 5 represents the TEM results of the perovskite quantum dots I and V. FIG. 6 includes a part (a) representing the TEM results of the perovskite quantum dots II; and a part (b) representing the high resolution TEM (HR-TEM) results and the Fast Fourier Transform (FFT) results of the perovskite quantum dots II.

According FIG. 5 and part (a) of FIG. 6, the perovskite quantum dots I of the example of the present invention and the perovskite quantum dots V of the comparative example have a sphere shape; and the perovskite quantum dots II of the example of the present invention have a cubic or rectangular shape, uniform size and the length below 50 nm in all three dimensions. Hence, neither does the perovskite quantum dots I of the examples and the perovskite quantum dots V of the comparative examples have a crystalline property. Whereas, the perovskite quantum dots II may be considered to have crystalline properties. Part (b) of FIG. 6 further shows that the perovskite quantum dots II of the example of the present invention have a lattice orientation of <100> and a lattice distance d(002) of 0.306 nm.

Subsequently, the layers including the perovskite quantum dots I, II and V are coated on substrates by means of various prior art such as spin coating, rod coating or blade coating to prepare the quantum dot film I, II and V.

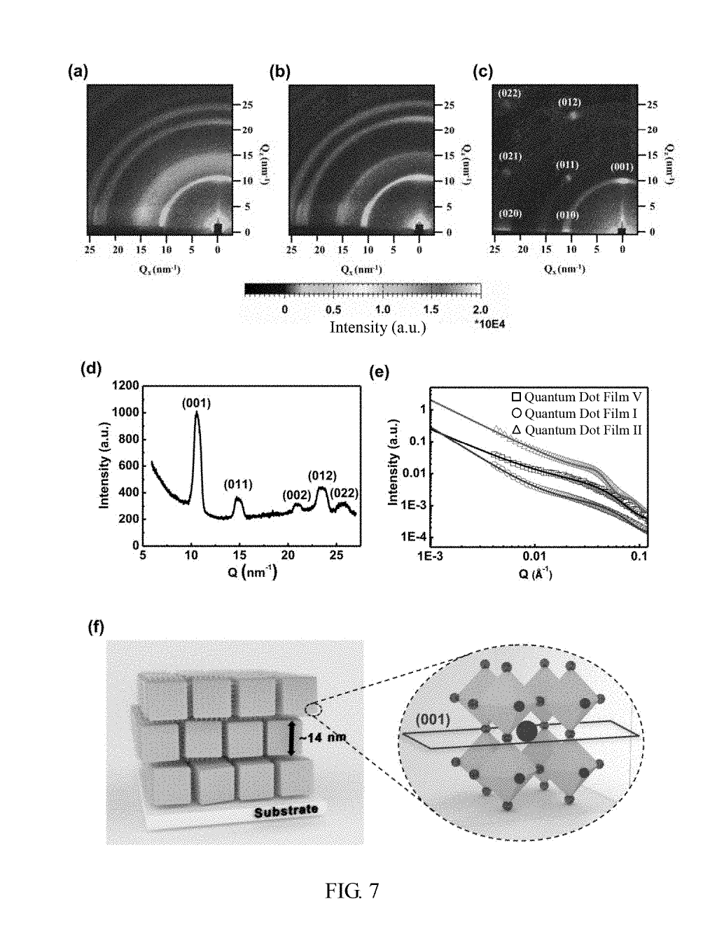

Part (a) of FIG. 7 shows the two-dimensional grazing incidence wide angle x-ray scattering (GIWAXS) results of the quantum dot film V. Part (b) of FIG. 7 shows the two-dimensional GIWAXS results of the quantum dot film I Parts (a) and (b) of FIG. 7 show that the quantum dot films I and V do not have directionality. Part (d) of FIG. 7 shows the diffraction peak of the quantum dot film II, and is similar to the X-ray diffraction (XRD) spectrum calculated from a single crystal (cubic system; space group: Pm 3̅ m, a=b=c=5.91 Å). The diffraction peak of spaces (001), (011), (002), (012) and (022) are located at where the scatter vectors Q=10.6 mn⁻¹, 15.0 nm⁻¹, 21.1 nm⁻¹, 23.6 nm⁻¹ and 26.0 nm⁻¹, respectively (corresponding to where XRD 2θ=15.0°, 21.2°, 30.2°, 33.9° and 37.2°, wherein Q=4π/λ sin θ; λ=wavelength of the X-ray; and θ is the diffraction angle.) The out-of-plane spot of part (c) of FIG. 7 shows that the (001) plane (having a d spacing of 5.91 Å of the quantum dot film II which is similar to the single crystal) is parallel to the substrate. Part (e) of FIG. 7 shows that the quantum dot films I and V are disorderly arranged, and the quantum dot film II is formed of the quantum dots II having a diameter of about 14 nm. Part (f) of FIG. 7 shows a schematic diagram of the quantum dot film II formed on a substrate.

Since the quantum dot film II has structural properties similar to a single crystal, it is considered to maintain the quantum yield of the quantum dot film II after filming, and the substantial effect is shown in FIG. 4. FIG. 4 shows a comparison between standardized fluorescent spectrums of the perovskite quantum dots II of solution form and the quantum dot film II formed by the same, wherein the perovskite quantum dots II of solution form is represented by the dashed line and the quantum dot film II formed by the same is represented by the solid line. In FIG. 4, the fluorescent spectrum of the perovskite quantum dots II of the solution form and the quantum dot film II formed by the same are almost identical to each other. The quantum yield of the quantum dot film II does not decrease because of the decreased distance therebetween, which proves that the quantum dot film II may maintain the fluorescent spectrum and quantum yield of the perovskite quantum dots II.

Stability Test

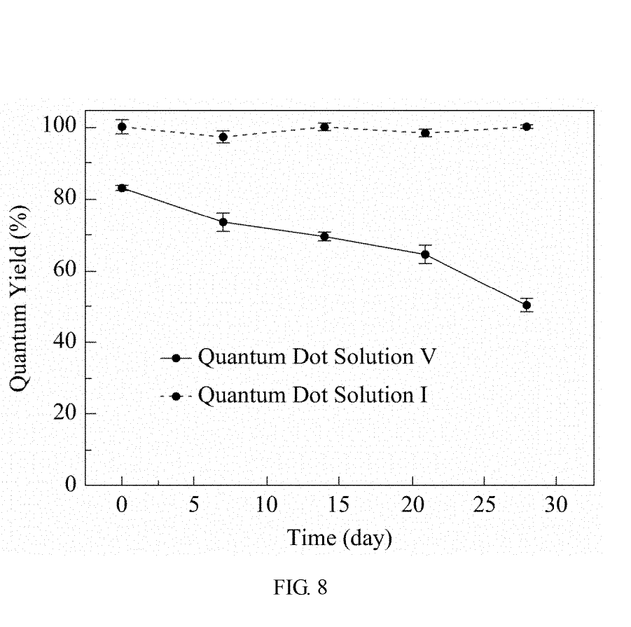

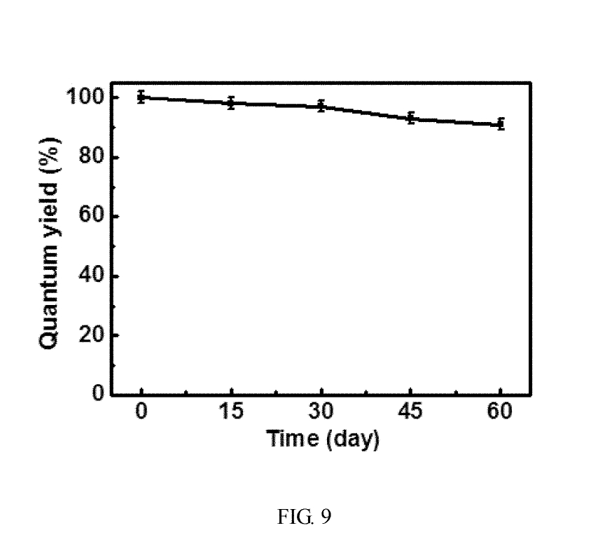

The change of quantum yield over time of quantum dot solutions I and V and the quantum dot film II are measured by an integrating sphere measuring system. The change of quantum yield over time of quantum dot solutions I and V are shown in FIG. 8; and the change quantum yield over time of the quantum dot film II is shown in FIG. 9.

According to FIGS. 8 and 9, the quantum yield of the quantum dot solution I and the quantum dot film II of the examples of the present invention are 10% higher than that of the quantum dot solution V and are approaching 100%. Further, according to FIGS. 8 and 9, the quantum yield of the quantum dot solution I may be maintained at about 100% for over 1 month; and the quantum yield of the quantum dot film II may be maintained at about 90% for over 2 months. Comparatively, the quantum yield of the quantum dot solution V decreases to about 50% after 1 month, that is, the quantum dot solution I and the quantum dot film II of the examples of the present invention not only provide a higher quantum yield but also have a much higher stability than that of the quantum dot solution V.

Such a difference is considered to be caused by the titration of the second precursor solution into the toluene which is the first poor solvent. In the comparative example adopting the titration, the second precursor solution is mixed with the first poor solvent in a form of large diameter and non-uniform droplets because of the limitations of the surface tension of the second precursor solution, so that the first poor solvent and the second precursor solution dropped therein are not able to react uniformly and the inner core of the quantum dots are not able to be completely covered by organic ligands. Since the organic ligands fail to completely cover the inner core, the quantum dots may be unstable because of the surface defect thereof. Further, the inner core of the quantum dots which had failed to be covered completely may self-aggregate to a perovskite nano-sheet or a nano-rod exceeding the demanded size such that the quantum yield is decreased. Comparatively, the perovskite quantum dots I and II of the examples of the present invention formed by the spraying method may provide droplets with uniform sizes and having a diameter lower to 10⁻¹˜10⁻² mm. Thus, the second precursor solution sprayed into the first poor solvent may react uniformly so that the problems of worse efficiency caused by excess sizes of the quantum dots and instability caused by undersized quantum dots may reduce, and the precipitation of the quantum dots may be accelerated since the surface area per unit volume increases. Also, the quantum dots with uniform sizes may facilitate the complete covering of the quantum dots by the organic ligands and thereby reducing the surface defects, avoiding self-aggregation and improving whole yield and stability of the quantum dots.

As mentioned above, it is clear that the quantum dot solutions I and II of the examples of the present invention have higher yield, quantum yield, stability, and have a light-emitting color purity greater than the quantum dot solution V of the comparative example; and the quantum dot film II has better quantum yield and stability than the quantum dot solution V. According to the preparation method of the pervoskite quantum dots, the perovskite quantum dots having better yield, quantum yield, stability and light-emitting color purity than that made of traditional titration method, and the quantum dot film having improved quantum yield and stability may be made of said perovskite quantum dots.

Since the perovskite quantum dots of the embodiment of the present invention have higher quantum yield and light-emitting color purity, and have a quantum yield close to 100% after filming, the light-emitting color purity and brightness may be improved when the quantum dot film of the embodiment of the present invention is utilized as a light-emitting layer or a light conversion layer in an electronic product.

When the quantum dot film of the embodiment of the present invention is utilized as a light conversion layer in a light-emitting display device, the light-emitting display device may further include a light source emitting blue light or UV light. Further, the quantum dot film utilized as the light conversion is disposed on the light source emitting blue light or UV light in order to convert the blue light and UV light to a demanded color.

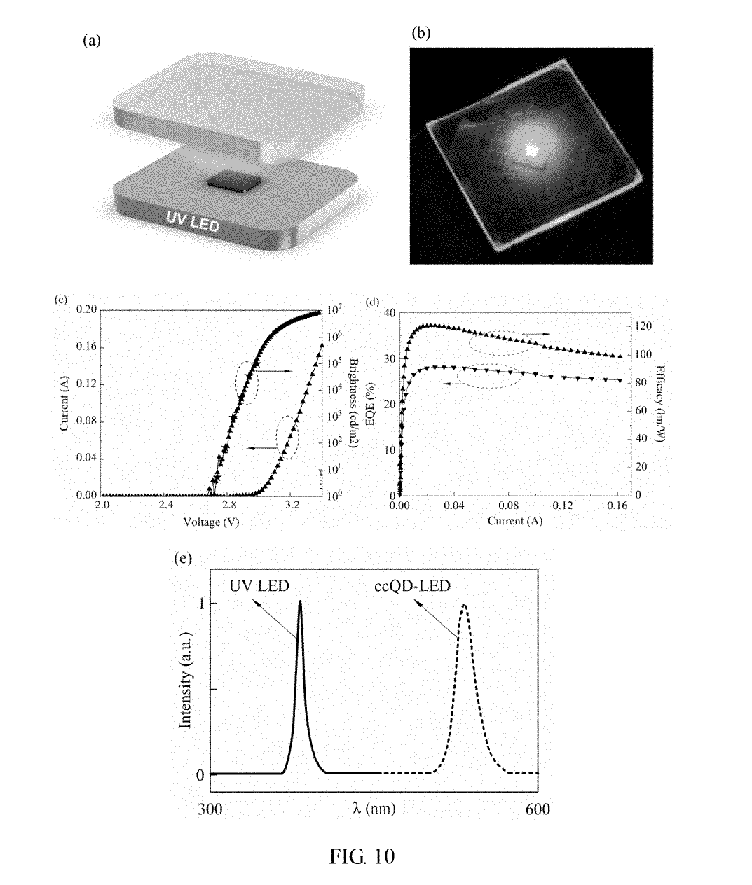

The part (a) of FIG. 10 shows a schematic diagram of utilizing the quantum dot film II of an example of the present invention as a light conversion layer applied in a light-emitting display device; the part (b) of FIG. 10 shows the photographs of the part (a). The part (c) of FIG. 10 shows a diagram of the IVL properties of the light-emitting display device shown in the part (a), wherein the asterisks represents the brightness measured by a spectroradiometer; the part (d) of FIG. 10 shows a diagram of the EQE and the efficacy of the light-emitting display device shown in the part (a); and the part (e) of FIG. 10 shows a emission spectra of the light-emitting display device (ccQD-LED) shown in the part (a) and a emission spectra of the light-emitting display device without comprising the quantum dot film II of the present invention (the UV-LED of the part (a) of FIG. 10).

According to FIG. 10, the quantum dot film of the embodiments of the present invention does not reduce the light-emitting brightness of the backlight source when utilized in a light-emitting display device, and the light-emitting display device including the quantum dot film of the embodiments of the present invention has great IVL properties, EQE and efficiency.

When the quantum dot film of the embodiments of the present invention is utilized as a light-emitting layer, the light-emitting display device may further include an electron supplying electrode and a hole supplying electrode, and the quantum dot film utilized as the light-emitting layer may be disposed between the electron supplying electrode and the hole supplying electrode. In an preferable embodiment, the light-emitting display device may further include a hole auxiliary layer located between the quantum dot film and the hole supplying electrode and facilitating the hole moving from the hole supplying electrode to the light-emitting layer, and an electron auxiliary layer located between the quantum dot film and the electron supplying electrode and facilitating an electron moving from the electron supplying electrode to the light emitting layer.

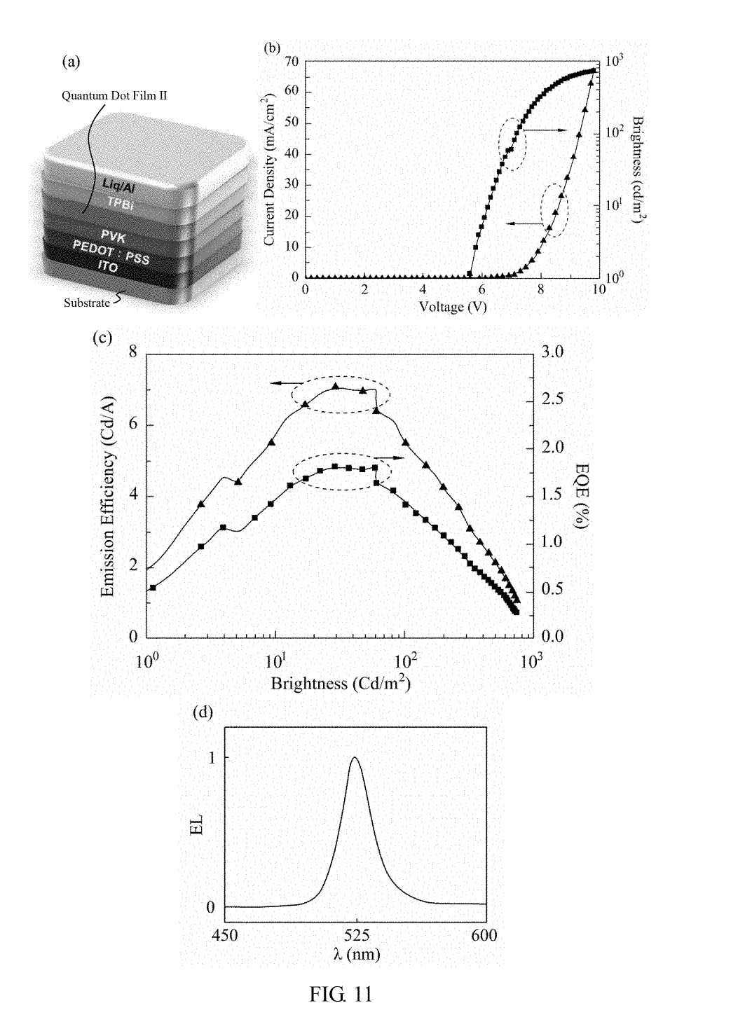

The part (a) of FIG. 11 shows a schematic diagram of utilizing the quantum dot film II of an example of the present invention as a light-emitting layer applied in a light-emitting display device; the part (b) of FIG. 11 shows a diagram of the J-V-L property of the light-emitting display device shown in the part (a); the part (c) of FIG. 11 shows a diagram of the EQE and the efficiency of the light-emitting display device shown in the part (a); and the part (d) illustrating a emission spectra of the light-emitting display device shown in the part (a).

According FIG. 11, when the quantum dot film of the embodiments of the present invention is utilized as a light-emitting layer in a light-emitting display device, the light-emitting display device has normal performance.

In addition, the quantum dot film may further be disposed on various things such as clothes or bicycles in order to improve interest or traffic safety. Further, since the perovskite quantum dots made of the preparation method provided by the embodiments of the present invention do not contain any heavy metals and have a high stability and high quantum yield, it may further be utilized as a fluorescent marker for tracing the distribution and metabolic conditions of interested substances in vivo or in the environment.

The above is merely exemplary and not intended to be limiting. Any equivalent modification or change without departing from the spirit and scope of the present invention should be included in the scope of the appending claims.

What is claimed is:

1. A method of preparing perovskite quantum dots, comprising:
adding an organic ligand into a first precursor solution prepared by a first halide and a second halide to form a second precursor solution, or adding the organic ligand into a first poor solvent to form a second poor solvent;
spraying the first precursor solution into the second poor solvent or spraying the second precursor solution into the first poor solvent by a spraying method to obtain a mixed solution comprising first perovskite quantum dots and second perovskite quantum dots;
centrifuging the mixed solution to obtain a supernatant and a precipitate; and
obtaining the first perovskite quantum dots and the second perovskite quantum dots from the supernatant and the precipitate, respectively,
wherein, the first perovskite quantum dots are different from the second perovskite quantum dots.

2. The method of preparing the perovskite quantum dots of claim 1, wherein the first halide is an inorganic metal halide of which the metal is selected from the group consisting of: Ge, Sn, Pb, Sb, Bi, Cu, Mn, Ca, In, Tl, Pd, Pt and combinations thereof.

3. The method of preparing the perovskite quantum dots of claim 1, wherein the second halide is an organic ammonium salt or an inorganic halide.

4. The method of preparing the perovskite quantum dots of claim 1, wherein the organic ligand comprises a carbon chain having at least 5 carbon atoms.

5. The method of preparing the perovskite quantum dots of claim 1, wherein the organic ligand comprises a compound represented by Formula 2 as follows:
CₙH₂ₙ₊₁NH₂ (Formula 2)
wherein, n is an integral selected from 1 to 30.

6. The method of preparing the perovskite quantum dots of claim 1, wherein the organic ligand comprises a compound represented by Formula 3 as follows:
CₙH₂ₙ₋₁COOH (Formula 3)
wherein, n is an integral selected from 1 to 30.

7. The method of preparing the perovskite quantum dots of claim 1, wherein droplets of the first precursor solution or the second precursor solution sprayed by the spraying method have a diameter of 10⁻¹˜10⁻² mm.

8. The method of preparing the perovskite quantum dots of claim 1, wherein the first perovskite quantum dot has a sphere shape, and the second perovskite quantum dot has a cube or rectangular shape.

9. A perovskite quantum dot, which is the first perovskite quantum dot or the second perovskite quantum dot prepared by the method of claim 1.

10. A quantum dot film, comprising the perovskite quantum dots of claim 9.
